(19) United States
(12) Patent Application Publication
(10) Pub. No.: US 2002/0153564 A1
(43) Pub. Date: Oct. 24, 2002

(54) Semiconductor device

(75) Inventor: Koji Shirai, Kawasaki-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, KAWASAKI-SHI (JP)

(21) Appl. No.: 09/801,740

(22) Filed: Mar. 9, 2001

(30) Foreign Application Priority Data
Mar. 10, 2000 (JP) 2000-067528

(51) Int. Cl. H01L 27/15; H01L 31/153; H01L 31/12

(52) U.S. Cl. 257/347; 257/84; 257/172

(57) ABSTRACT

A semiconductor device includes a substrate and a semiconductor layer of a first conductivity type, formed over the substrate via an insulating layer, the semiconductor layer having a protective diode. The protective diode has a first diffusion layer of a second conductivity type, formed in the semiconductor layer, a second diffusion layer of the second conductivity type, formed in the semiconductor layer, the second diffusion layer being isolated from the first diffusion layer, a third diffusion layer of the first conductivity type, formed in a region of the semiconductor layer, the region being sandwiched between the first and the second diffusion layers, the third diffusion layer being contact with the second diffusion layer, a first electrode formed as being contact with the first diffusion layer and a second electrode formed as being contact with the second and the third diffusion layers. The second diffusion layer may be formed as surrounding the first diffusion layer but being isolated from the first diffusion layer.

### CROSS REFERENCE TO RELATED APPLICATIONS

This application claims benefit of priority under 35USC §119 to Japanese Patent Application No. 2000-67528 filed on Mar. 10, 2000 in Japan, the entire contents of which are incorporated by reference herein.

### BACKGROUND OF THE INVENTION

The present invention relates to a semiconductor device fabricated with dielectric isolation. Particularly, this invention relates to a protective diode for such a semiconductor device.

Illustrated in FIG. 1 is a known pn-junction diode as an ESD (electrostatic Discharge)-protective diode for a semiconductor device with a SOI (silicon ON Insulator)-substrate.

In FIG. 1, the protective diode is provided with an anode layer 4 and a cathode layer 5 formed in a silicon layer 3 isolated from a silicon substrate 1 via an insulating layer 2.

A positive high-voltage surge pulse supplied to the protective diode via a cathode K causes avalanche breakdown so that the surge pulse passes from the cathode layer 5 to the anode layer 4 as a breakdown current.

The breakdown initially occurs at the surface of the silicon layer 3 for which the maximum reverse bias electric field will be applied. The breakdown current is thus converged on the surface of the silicon layer 3 to generate heat locally which could cause device fracture due to crystal fracture.

A disadvantage of the pn-junction diode shown in FIG. 1 thus lies in low ESD-fracture toughness in which a reverse bias electric field will be generated.

Illustrated in FIG. 2 is a known ESD-protective diode with pnp-transistor structure.

Formed in a silicon substrate 3 are a P-type collector layer 4 and a P-type emitter layer 6 isolated from each other. Formed outside the emitter layer 6 is an n⁺-type layer 7 (a base-contact layer) as being contact with the emitter layer 6. A cathode electrode K is formed so that it is contact with both the emitter layer 6 and the n⁺-type layer 7.

This structure offers a protective diode that is equivalent to a pnp-transistor, the base and emitter being short-circuited.

In FIG. 2, a positive high-voltage surge pulse supplied to the cathode K causes punch-through breakdown so that a depletion layer extending from the p-type collector 4 reaches a depletion layer around the p-type emitter 6 to cause a flow of punch-through current between the collector and emitter.

Compared to the protective diode shown in FIG. 1, convergence of current is eased for the protective diode shown in FIG. 2 due to difference in type of breakdown.

However, this diode also has convergence of a breakdown current on the surface of the silicon layer and thus suffers from device fracture due to generation of high-voltage (or large-current) surge pulses.

### SUMMARY OF THE INVENTION

A purpose of the present invention is to provide a SOI-semiconductor device having high ESD-fracture toughness.

A semiconductor device including: a substrate; and a semiconductor layer of a first conductivity type, formed over the substrate via an insulating layer, the semiconductor layer including a protective diode having: a first diffusion layer of a second conductivity type, formed in the semiconductor layer; a second diffusion layer of the second conductivity type, formed in the semiconductor layer, the second diffusion layer being isolated from the first diffusion layer; a third diffusion layer of the first conductivity type, formed in a region of the semiconductor layer, the region being sandwiched between the first and the second diffusion layers, the third diffusion layer being contact with the second diffusion layer; a first electrode formed as being contact with the first diffusion layer; and a second electrode formed as being contact with the second and the third diffusion layers.

Moreover, the present invention provides a semiconductor device including: a substrate; and a semiconductor layer of a first conductivity type, formed over the substrate via a first insulating film, the semiconductor layer including a protective diode having; a first diffusion layer of a second conductivity type, formed in the semiconductor layer; a second diffusion layer of the second conductivity type, formed in the semiconductor layer as surrounding the first diffusion layer, the second diffusion layer being isolated from the first diffusion layer; a third diffusion layer of the first conductivity type, formed in a region of the semiconductor layer, the region being sandwiched between the first and the second diffusion layers, the third diffusion layer being contact with the second diffusion layer; a first electrode formed as being contact with the first diffusion layer; and a second electrode formed as being contact with the second and the third diffusion layers.

### BRIEF DESCRIPTION OF DRAWINGS

FIG. 1 is a sectional view showing a known protective diode;

FIG. 2 is a sectional view showing another known protective diode;

FIG. 3 is a plan view showing the first preferred embodiment of a protective diode according to the present invention;

FIG. 4 is a sectional view taken on line A-A′ of FIG. 3;

FIG. 5 illustrates development of a depletion layer in the first embodiment of the protective diode;

FIG. 6 is a sectional view showing a major section of the second preferred embodiment of a protective diode according to the present invention;

FIG. 7 is a sectional view showing the third preferred embodiment of a protective diode according to the present invention; and

FIG. 8 is a sectional view taken on line A-A′ of FIG. 7.

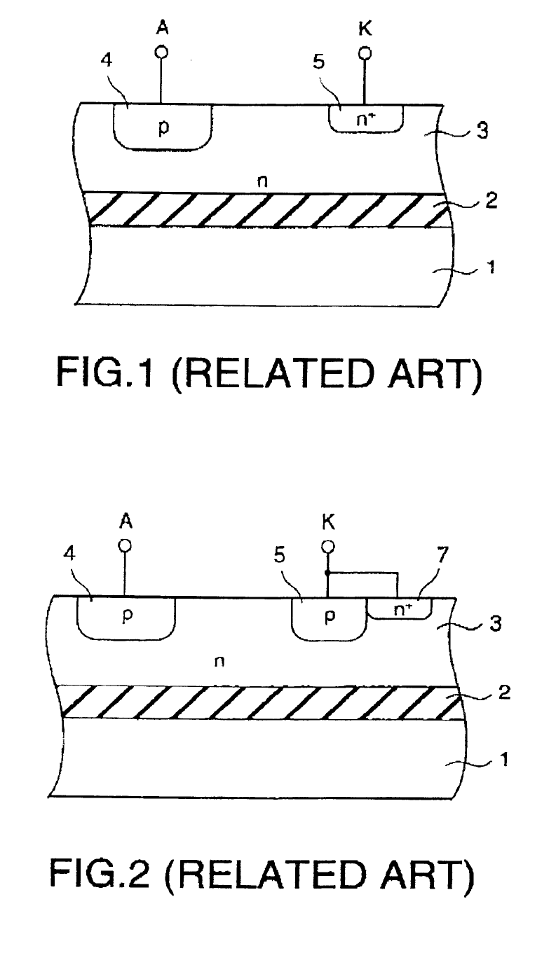

### DETAILED DESCRIPTION OF PREFERRED EMBODIMENTS

According to this invention, when the first and the second conductivity types are an n-type and a p-type, respectively, the protective diode is a pn-junction diode for which the first and the second diffusion layers are an anode and cathode, respectively, which is equivalent to a pnp-transistor, the emitter and the base thereof being short-circuited.

In this structure according to the present invention, a positive high-voltage surge pulse supplied to the cathode causes punch-through breakdown, however, the third diffusion layer formed as being contact with the second diffusion layer prevents depletion layers developed between the first and the second diffusion layers from being united on the device surface, thus punch-through occurring in the semiconductor layer to obstruct convergence of a breakdown current to the device surface.

Therefore, the present invention achieves high ESD-fracture toughness.

Preferred embodiments according to the present invention will be disclosed with reference to the attached drawings.

(First Embodiment)

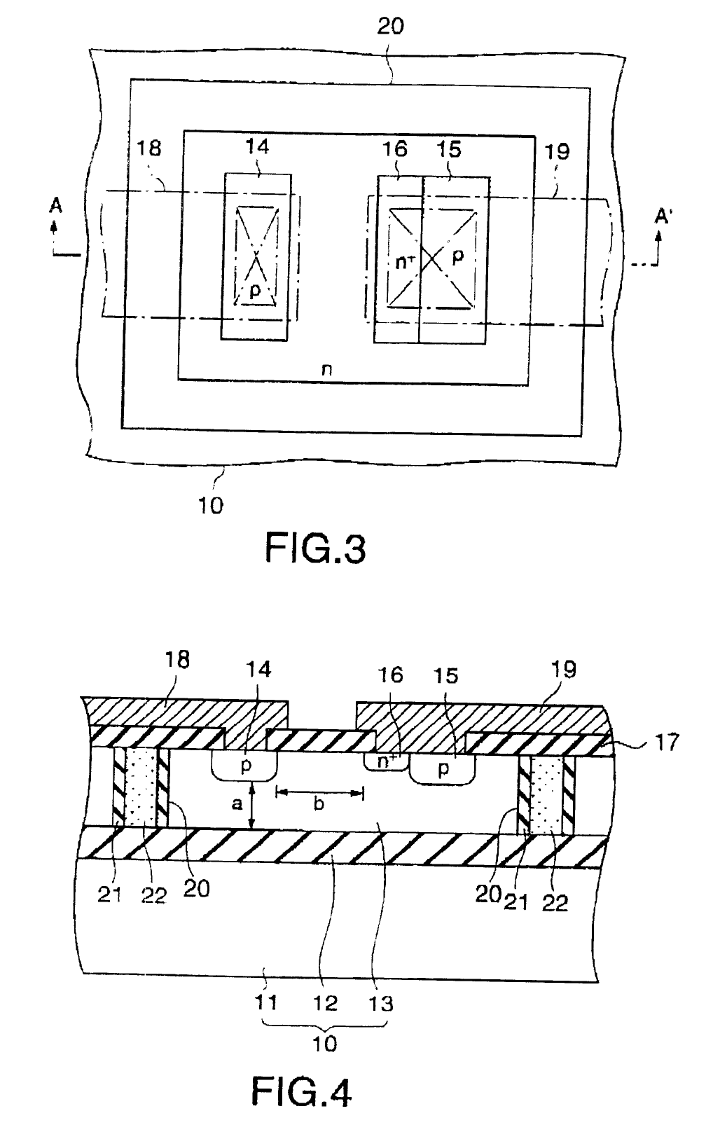

FIG. 3 shows a layout of a protective diode formed in a semiconductor device as the first preferred embodiment according to the present invention. FIG. 4 is a sectional view taken on A-A′ of FIG. 3.

An SOI-substrate 10 consists of a silicon substrate 11 and an n⁺-type silicon layer 13 (an active layer) isolated via an insulating layer 12 (made of a silicon oxide film, etc.). The silicon substrate 11 and the silicon layer 13 are bonded to each other via the insulating layer 12 after the layer 12 has been formed either on the substrate 11 or under the layer 13.

Two p-type diffusion layers 14 and 15 are formed in the silicon layer 13 as being separated from each other. The p-type diffusion layer 14 functions as an anode layer. The other p-type diffusion layer 15 is formed with an n⁺-type diffusion layer 16 functioning as a cathode layer, as being contact with the diffusion layer 15 and facing the diffusion layer 14. In other words, the n⁺-type diffusion layer 16 is formed as being contact with the diffusion layer 15 in the area sandwiched between the layers 14 and 15.

The n⁺-type diffusion layer 16 is formed as being thinner than the p-type diffusion layer 15 in the direction of depth towards the substrate 10, thus the distance between the bottom surface of the layer 16 and the substrate 10 is longer than that between the bottom surface of the layer 15 and the substrate 10.

An anode electrode 18 is contact with the p-type diffusion layer 14. A cathode electrode 19 is contact with both the p-type diffusion layer 15 and the n⁺-type diffusion layer 16. The electrodes 18 and 19 are provided on an insulating film 17 that covers the silicon layer 13.

The protective diode region is isolated in the lateral direction by an insulating film 21 formed in a groove 20. The groove 20 that reaches the insulating layer 12 is also filled with polycrystal silicon 22, to form a device isolation region.

In this embodiment, it is preferable that a distance “b” between the p-type diffusion layer 14 and the n⁺-type diffusion layer 16 is longer than a distance “a” between the bottom surface of the layer 14 and the insulating layer 12.

In this protective diode, a positive high-voltage surge pulse supplied to the cathode side causes punch-through breakdown so that a depletion layer extending from the p-type diffusion layer 14 (anode side) reaches the p-type diffusion layer 15 (cathode side) to cause punch-through breakdown.

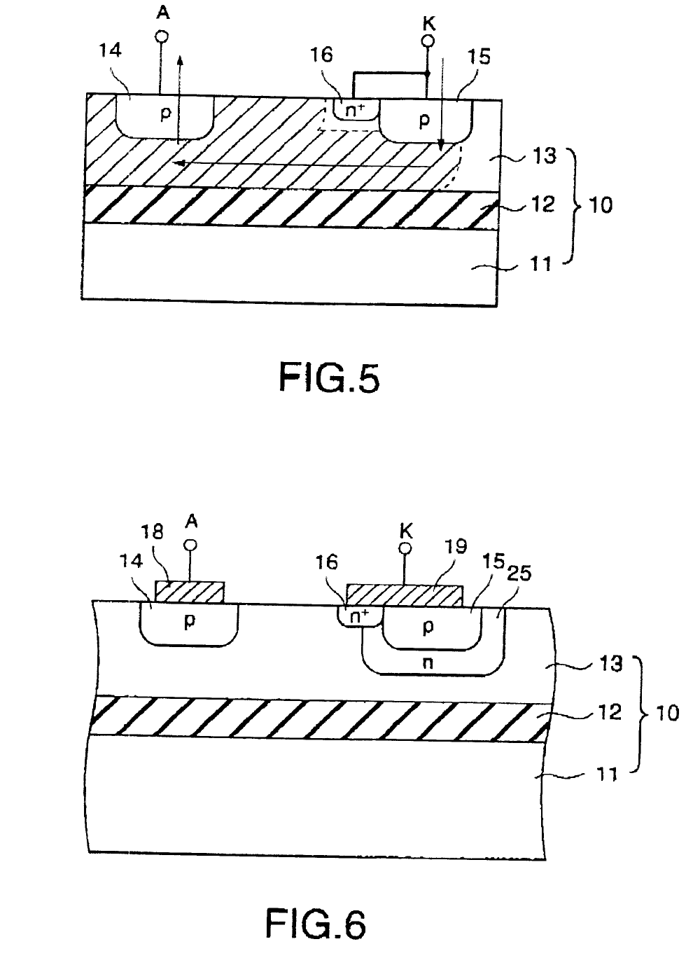

As indicated by a dashed line in FIG. 5, the depletion layer also extends along the surface of the silicon layer 13, which is, however, obstructed by the n⁺-type diffusion layer 16 that is contact with the p-type diffusion layer 15 (cathode side). The depletion layer then extends downwardly to reach the insulation layer 12. It further extends in the lateral direction along the insulation layer 12 to reach the p-type diffusion layer 15, or reach a depletion layer that surrounds the layer 15, thus causing punch-through in the device with a breakdown current flowing through the silicon layer 13 from the cathode to anode side as indicated by an arrow in FIG. 5.

The structure in which the distance “b” between the p-type diffusion layer 14 and the n⁺-type diffusion layer 16 is longer than the distance “a” between the bottom surface of the layer 14 and the insulating layer 12 obstructs the depletion layer extending in the lateral direction so as not to reach the layer 16 until the depletion layer extending downwardly from the layer 14 reaches the layer 12.

This structure is a preferable requirement of avoiding breakdown at least on the device surface until a depletion layer is formed between the p-type diffusion layer 14 and the insulating layer 12 and the depletion layer extending in the lateral direction reaches the p-type diffusion layer 15.

As disclosed, according to the first embodiment of the protective diode, punch-through occurs in the silicon layer 13, thus preventing a breakdown current from being converged on the device surface.

The present invention therefore achieves high ESD-fracture toughness with no device fracture.

(Second Embodiment)

FIG. 6 illustrates a major section of the second preferred embodiment of a protective diode according to the present invention.

Elements in this embodiment that are the same as or analogous to elements in the first embodiment (FIG. 4) are referenced by the same reference numbers and will not be explained in detail. Moreover, several elements in this embodiment that are the same as or analogous to elements in the first embodiment, such as, the insulating layer 12, are omitted in FIG. 6 for brevity.

The difference between the first and the second embodiments is only that, in the latter, the p-type diffusion layer 15 (cathode side) is formed in an n-type diffusion layer 25.

A silicon layer in SOI-structure, such as the silicon layer 13, varies in thickness and impurity concentration due to variation in punch-through withstanding voltage.

The second embodiment, however, can relatively freely control a punch-though voltage by controlling impurity concentration of the n-type diffusion layer 25 that surrounds the p-type diffusion layer 15 (cathode side). The impurity concentration of the layer 25 higher than that of the silicon layer 13 by, for example, single figure or double figures or more serves to raise a punch-through voltage with rare occurrence of punch-through.

(Third Embodiment)

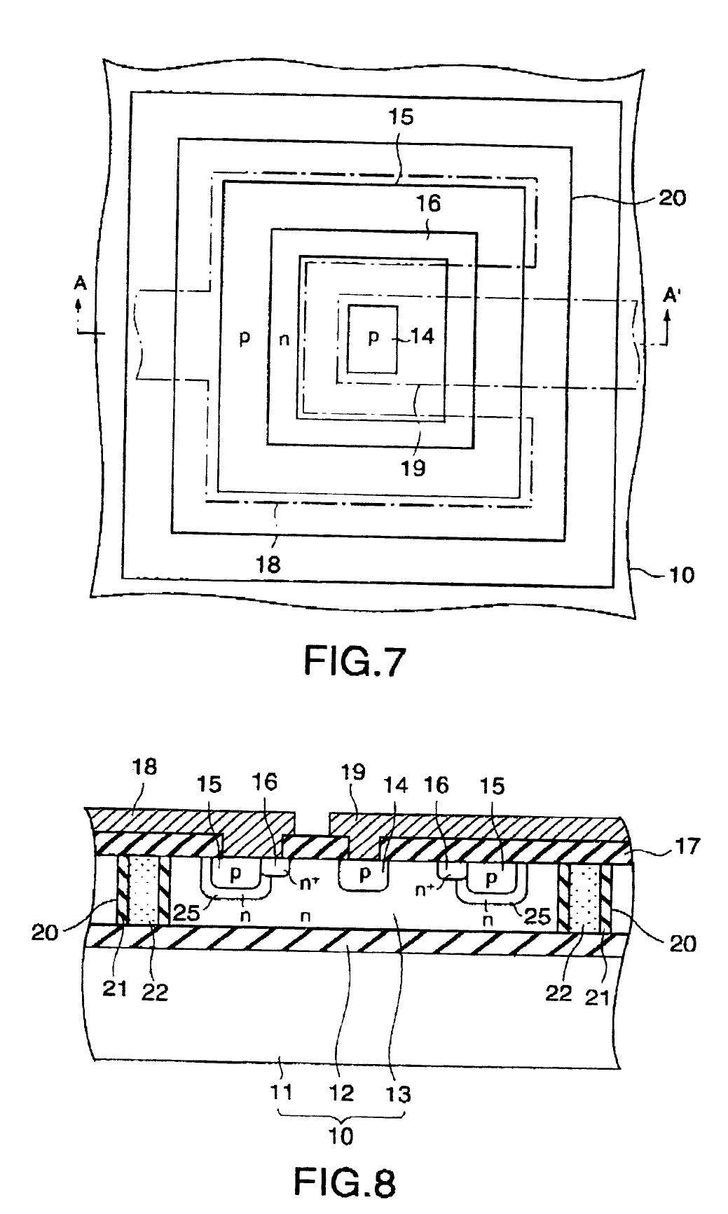

FIG. 7 shows a layout of a protective diode formed in a semiconductor device as the third preferred embodiment according to the present invention. FIG. 8 is a sectional view taken on A-A′ of FIG. 7.

Elements in this embodiment that are the same as or analogous to elements in the first embodiment (FIGS. 3 and 4) are referenced by the same reference numbers and will not be explained in detail.

The difference between the first and the third embodiments is only that, in the latter, the p-type diffusion layer 15 (cathode layer) and the n-type diffusion layer 16 are formed to surround the p-type diffusion layer 15 (anode layer) with a predetermined distance therebetween.

In this embodiment, it is also preferable that the distance between the p-type diffusion layer 14 and the n⁺-type diffusion layer 16 is longer than that between the bottom surface of the layer 14 and the insulating layer 12.

Like the second embodiment (FIG. 6), the third embodiment is provided with the p-type diffusion layer 15 (cathode side) formed inside the n-type diffusion layer 25. The n-type diffusion layer 25 is, however, not always required.

The third embodiment also achieves high ESD-fracture toughness like the first and the second embodiments.

It is further understood by those skilled in the art that the foregoing descriptions are preferred embodiments of the disclosed device and that various change and modification may be made in the invention without departing from the spirit and scope thereof.

For example, the above embodiments are provided with a protective diode formed in an n-type silicon layer of an SOI-substrate, however, it also can be formed in a p-type silicon substrate against a negative high ESD with a device structure composed by reverse conductivity-type elements with respect to the counterparts in the above embodiments.

In that structure, a protective diode is formed as being equivalent to an npn-transistor in which the emitter and base are short-circuited.

As disclosed above, the present invention offers a protective diode for an SOI-semiconductor device with high ESD-fracture toughness.

What is claimed is:

1. A semiconductor device comprising:
a substrate; and
a semiconductor layer of a first conductivity type, formed over the substrate via an insulating layer, the semiconductor layer including a protective diode having:
a fist diffusion layer of a second conductivity type, formed in the semiconductor layer;
a second diffusion layer of the second conductivity type, formed in the semiconductor layer, the second diffusion layer being isolated from the first diffusion layer;
a third diffusion layer of the first conductivity type, formed in a region of the semiconductor layer, the region being sandwiched between the first and the second diffusion layers, the third diffusion layer being contact with the second diffusion layer;
a first electrode formed as being contact with the first diffusion layer; and
a second electrode formed as being contact with the second and the third diffusion layers.

2. The semiconductor device according to claim 1, wherein a distance between the first and the third diffusion layers is longer than a distance between a bottom surface of the first diffusion layer and the insulating layer, the bottom surface being closer to the substrate than an upper surface of the first diffusion layer.

3. The semiconductor device according to claim 1 further comprising a fourth diffusion layer of the first conductivity type, the second diffusion layer being formed as surrounded by the fourth diffusion layer.

4. The semiconductor device according to claim 3, wherein the fourth diffusion layer has impurity concentration higher than impurity concentration of the semiconductor layer.

5. The semiconductor device according to claim 1 further comprising an insulating film, the protective diode being isolated by the insulating film in a lateral direction parallel to the substrate in the semiconductor layer.

6. The semiconductor device according to claim 1 wherein the third diffusion layer is thinner than the second diffusion layer in a direction of depth towards the substrate, a distance between a bottom surface of the third diffusion layer and the substrate being longer than a distance between a bottom surface of the second diffusion layer and the substrate, the bottom surfaces being closer to the substrate than upper surfaces of the second and the third diffusion layers.

7. The semiconductor device according to claim 1 wherein the semiconductor layer is formed as being integrated with the substrate via the insulating layer.

8. The semiconductor device according to claim 5 wherein the semiconductor layer is partially surrounded by the insulating layer and the insulating film, thus the semiconductor layer being isolated from neighboring semiconductor devices.

9. The semiconductor device according to claim 1 wherein the first conductivity type is an n-type while the second conductivity type is a p-type, the protective diode absorbing a positive high-voltage surge.

10. The semiconductor device according to claim 1 wherein the first conductivity type is a p-type while the second conductivity type is an n-type, the protective diode absorbing a negative high-voltage surge.

11. A semiconductor device comprising:
a substrate; and
a semiconductor layer of a first conductivity type, formed over the substrate via an insulating layer, the semiconductor layer including a protective diode having:
a first diffusion layer of a second conductivity type, formed in the semiconductor layer;
a second diffusion layer of the second conductivity type, formed in the semiconductor layer as surrounding the first diffusion layer, the second diffusion layer being isolated from the first diffusion layer;
a third diffusion layer of the first conductivity type, formed in a region of the semiconductor layer, the region being sandwiched between the first and the second diffusion layers, the third diffusion layer being contact with the second diffusion layer;
a first electrode formed as being contact with the first diffusion layer; and
a second electrode formed as being contact with the second and the third diffusion layers.

12. The semiconductor device according to claim 11, wherein a distance between the first and the third diffusion layers is longer than a distance between a bottom surface of the first diffusion layer and the insulating layer, the bottom surface being closer to the substrate than an upper surface of the first diffusion layer.

13. The semiconductor device according to claim 11 further comprising a fourth diffusion layer of the first conductivity type, the second diffusion layer being formed as surrounded by the fourth diffusion layer.

14. The semiconductor device according to claim 13, wherein the fourth diffusion layer has impurity concentration higher than impurity concentration of the semiconductor layer.

15. The semiconductor device according to claim 11 further comprising an insulating film, the protective diode being isolated by the insulating film in a lateral direction parallel to the substrate in the semiconductor layer.

16. The semiconductor device according to claim 11 wherein the third diffusion layer is thinner than the second diffusion layer in a direction of depth towards the substrate, a distance between a bottom surface of the third diffusion layer and the substrate being longer than a distance between a bottom surface of the second diffusion layer and the substrate, the bottom surfaces being closer to the substrate than upper surfaces of the second and the third diffusion layers.

17. The semiconductor device according to claim 11 wherein the semiconductor layer is formed as being integrated with the substrate via the insulating layer.

18. The semiconductor device according to claim 15 wherein the semiconductor layer is partially surrounded by the insulating layer and the insulating film, thus the semiconductor layer being isolated from neighboring semiconductor devices.

19. The semiconductor device according to claim 11 wherein the first conductivity type is an n-type while the second conductivity type is a p-type, the protective diode absorbing a positive high-voltage surge.

20. The semiconductor device according to claim 11 wherein the first conductivity type is a p-type while the second conductivity type is an n-type, the protective diode absorbing a negative high-voltage surge.
